(19) United States
(12) Patent Application Publication
(10) Pub. No.: US 2014/0015091 A1
(43) Pub. Date: Jan. 16, 2014

(54) SEMICONDUCTOR DEVICE, METHOD OF MANUFACTURING SEMICONDUCTOR DEVICE, AND SOI SUBSTRATE

(71) Applicant: Noriaki Matsuno, Kanagawa (JP)

(72) Inventor: Noriaki Matsuno, Kanagawa (JP)

(73) Assignee: Renesas Electronics Corporation

(21) Appl. No.: 14/006,939

(22) PCT Filed: Feb. 21, 2012
(86) PCT No.: PCT/JP2012/001161

§ 371 Date: Sep. 23, 2013

(30) Foreign Application Priority Data
Mar. 25, 2011 (JP) 2011-067013

(51) Int. Cl. H01L 27/02; H01L 21/761

(52) U.S. Cl. CPC H01L 27/0203; H01L 21/761
USPC 257/504; 438/414

(57) ABSTRACT

Provided is a semiconductor device showing stable high-frequency characteristics.

A semiconductor device includes the following configuration. A diffusion region into which acceptors are introduced is formed in a silicon substrate. In addition, a non-diffusion region into which the acceptors are not introduced is disposed in the silicon substrate alternately with the diffusion region. In addition, a first insulating layer is provided so as to contact with the silicon substrate. Further, an interconnect is provided on the first insulating layer.

### TECHNICAL FIELD

The present invention relates to a semiconductor device, a method of manufacturing a semiconductor device, and an SOI substrate.

### BACKGROUND ART

Recently, in high frequency integrated circuits using a silicon substrate, it has been required to prevent signal attenuation caused by a dielectric loss of the silicon substrate.

Patent Document 1 (Japanese Unexamined Patent Publication No. 2008-227084) discloses a semiconductor device in which boron used as an acceptor is introduced into a region that comes into contact with a silicon oxide film on a silicon substrate. With such a configuration, a boron doping layer serves as a hole source, and charge compensation is performed on electrons collected in the vicinity of the interface. Therefore, it is possible to reduce the number of interface carriers that contribute to electrical conduction, and to realize a semiconductor device having low harmonics.

### RELATED DOCUMENT

### Patent Document

[Patent Document 1] Japanese Unexamined Patent Publication No. 2008-227084

### DISCLOSURE OF THE INVENTION

### Problem to be Solved by the Invention

However, as a result of examination by the inventor, it has been found, as disclosed in Patent Document 1, that in a method of doping the entire surface of the silicon oxide film interface with acceptors using an ion implantation, there is the possibility of high-frequency characteristics being deteriorated when due to the variations of interfacial electron density, doping amount, or the like.

### Means For Solving Problem

According to the present invention, there is provided a semiconductor device including: a diffusion region which is provided in a silicon substrate, and into which acceptors are introduced; a non-diffusion region which is disposed in the silicon substrate alternately with the diffusion region, and into which the acceptors are not introduced; a first insulating layer which is provided so as to contact with the silicon substrate; and an interconnect which is provided over the first insulating layer.

According to the present invention, there is provided a method of manufacturing a semi conductor device, including: a first process of forming a first insulating layer over a silicon substrate, and forming a diffusion region into which acceptors are introduced and a non-diffusion region which is disposed alternately with the diffusion region and into which the acceptors are not introduced, in the silicon substrate; and forming an interconnect over the first insulating layer.

According to the present invention, there is provided an SOI substrate including: a diffusion region which is provided in a silicon substrate, and into which acceptors are introduced; a non-diffusion region which is disposed in the silicon substrate alternately with the diffusion region, and into which the acceptors are not introduced; a first insulating layer which is provided so as to contact with the top of the silicon substrate; and a silicon layer which is provided so as to contact with the top of the first insulating layer.

According to the present invention, a diffusion region into which acceptors are introduced and a non-diffusion region into which the acceptors are not introduced are alternately disposed in a silicon substrate. Here, the diffusion region into which the acceptors are introduced serves as a p-type region in the vicinity of the surface of the silicon substrate. On the other hand, the non-diffusion region into which the acceptors are not introduced serves as an n-type region due to interfacial electrons. In this manner, the p-type region and the n-type region are alternately formed. Thereby, electrons and holes generated in the vicinity of the surface of the silicon substrate are confined by a mutual potential barrier. Therefore, it is possible to effectively increase the resistivity of the silicon substrate. In addition, when the interfacial electron density varies in the plane, it is possible to reduce the influence thereof. As stated above, when a high frequency is applied, it is possible to suppress the influence of carriers generated in the vicinity of the surface of the silicon substrate.

### Advantage of the Invention

According to the present invention, when a high frequency is applied, it is possible to suppress the influence of carriers generated in the vicinity of the surface of the silicon substrate.

### BRIEF DESCRIPTION OF THE DRAWINGS

The above-mentioned objects, other objects, features and advantages will be made clearer from the preferred embodiments described below, and the following accompanying drawings.

FIG. 1 is a diagram illustrating a configuration of a semiconductor device according to a first embodiment.

FIG. 2 is a cross-sectional view illustrating a method of manufacturing the semiconductor device according to the first embodiment.

FIG. 3 is a diagram illustrating an effect of the first embodiment.

FIG. 4 is a diagram illustrating a configuration of a semiconductor device according to a second embodiment.

FIG. 5 is a cross-sectional view illustrating a method of manufacturing the semiconductor device according to the second embodiment.

FIG. 6 is a diagram illustrating a configuration of a semiconductor device according to a third embodiment.

FIG. 7 is an enlarged cross-sectional view of a portion A in FIG. 6.

FIG. 8 is a plan view illustrating a configuration of a semiconductor device according to a third embodiment.

FIG. 9 is a cross-sectional view illustrating a method of manufacturing the semiconductor device according to the third embodiment.

FIG. 10 is a cross-sectional view illustrating a method of manufacturing the semiconductor device according to the third embodiment.

FIG. 11 is a cross-sectional view illustrating a method of manufacturing a semiconductor device according to a fourth embodiment.

FIG. 12 is a plan view illustrating a configuration of a semiconductor device according to a fifth embodiment.

FIG. 13 is a plan view illustrating a configuration of the semiconductor device according to the fifth embodiment.

FIG. 14 is a plan view illustrating a configuration of the semiconductor device according to the fifth embodiment.

FIG. 15 is a plan view illustrating a configuration of the semiconductor device according to the fifth embodiment.

FIG. 16 is a plan view illustrating a configuration of a semiconductor device according to a sixth embodiment.

### DESCRIPTION OF EMBODIMENTS

Hereinafter, embodiments of the invention will be described with reference to the accompanying drawings. In all the drawings, like elements are referenced by like reference numerals and descriptions thereof will not be repeated.

(First Embodiment)

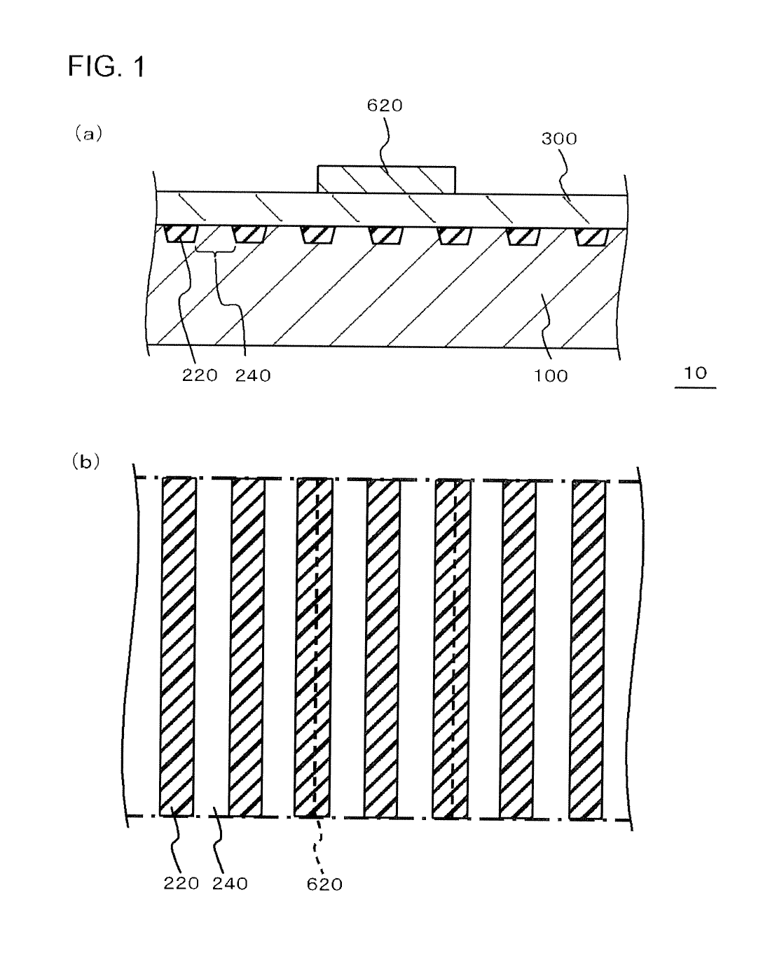

FIG. 1 is a diagram illustrating a configuration of a semiconductor device according to a first embodiment.

Meanwhile, FIG. 1(a) is a cross-sectional view illustrating Of a configuration of a semiconductor device 10. In addition, FIG. 1(b) is a plan view in the vicinity of the surface of a silicon substrate 100. The semiconductor device 10 includes the following configuration. Diffusion regions 220 into which acceptors are introduced are formed in the silicon substrate 100. In addition, a non-diffusion region 240 into which the acceptors are not introduced is disposed in the silicon substrate 100 alternately with the diffusion region 220. In addition, a first insulating layer 300 is provided so as to contact with the silicon substrate 100. Further, an interconnect 620 is provided on the first insulating layer 300. Hereinafter, a detailed description will be given.

Meanwhile, the silicon substrate 100 herein has a high resistivity of equal to or more than several kΩcm.

As shown in FIG. 1(a), the diffusion regions 220 into which the acceptors are introduced are formed in the silicon substrate 100. As described later, the introduction of the acceptors is performed by, for example, an ion implantation. The acceptor is, for example, B (boron). Thereby, the diffusion region 220 is formed of a p-type region.

In addition, the non-diffusion region 240 into which the acceptors are not introduced is disposed in the silicon substrate 100 alternately with the diffusion region 220.

Meanwhile, the non-diffusion region 240 is formed of an n-type region by interfacial electrons generated in the vicinity of the surface of the silicon substrate 100. Meanwhile, in the following description, a carrier generated in the vicinity of the surface of the silicon substrate 100 is represented as an “interface carrier”. Meanwhile, the term “vicinity of the surface of the silicon substrate 100” herein means the vicinity of the interface on the silicon substrate 100 side in the vicinity of the interface between the silicon substrate 100 and the first insulating layer 300.

In addition, the first insulating layer 300 is provided so as to contact with the silicon substrate 100. A high frequency signal is applied to the semiconductor device 10, and thus the first insulating layer 300 preferably has a low dielectric constant. The first insulating layer 300 is, for example, a silicon oxide film. Alternatively, the first insulating layer 300 may be a film which is a stack of plural kinds of insulating layers.

Further, the interconnect 620 is provided on the first insulating layer 300. The interconnect 620 is a transmission line to which a high frequency signal is applied. Here, a frequency F (GHz) of the high frequency signal applied to the interconnect 620 is, for example, equal to or more than 0.1 (GHz).

Next, the diffusion region 220 and the non-diffusion region 240 will be described in detail.

As shown in FIG. 1(b), the diffusion region 220 and the non-diffusion region 240 includes a long side in a direction parallel to the extending direction of the interconnect 620. In the first embodiment, the diffusion region 220 has, for example, a stripe shape, and is disposed parallel to the extending direction of the interconnect 620.

In addition, for example, the diffusion regions 220 adjacent to each other are separated. That is, in a range where the interconnect 620 extends, there is no portion that adjacent diffusion regions 220 are connected, when seen in a plan view. Thereby, it is possible to prevent carrier transport from a diffusion region 220 to an adjacent diffusion region 220 due to a high frequency signal.

In addition, the diffusion region 220 and the non-diffusion region 240 are alternately disposed. Here, these regions are alternately disposed in a direction perpendicular to the extending direction of the interconnect 620. When a high frequency signal is applied to the interconnect 620, an electric field induced by the high frequency signal in an interface direction is generated in the vicinity of the surface of the silicon substrate 100. Therefore, in this manner, the diffusion region 220 and the non-diffusion region 240 are alternately disposed in the direction perpendicular to the extending direction of the interconnect 620, and thus it is possible to suppress the interface carrier transport.

In addition, when the frequency of the high frequency signal applied to the interconnect 620 is set to F (GHz), the length of the diffusion region 220 on the short side in a direction parallel or perpendicular to the extending direction of the interconnect 620 is equal to or less than 25/F (μm). On the other hand, the length of the non-diffusion region 240 on the short side in a direction parallel or perpendicular to the extending direction of the interconnect 620 is equal to or less than 25/F (μm).

The “length of the diffusion region 220 on the short side” in the first embodiment is a length (width of the stripe) in the direction perpendicular to the extending direction of the diffusion region 220. The “length of the non-diffusion region 240 on the short side” is the same as well.

Here, the electric field in the interface direction generated in the vicinity of the surface of the silicon substrate 100 alternates with a period of 1/(2F) seconds. On the assumption that a typical saturation velocity of the carriers in silicon is 1×10⁷ cm/s, the distance in which the carrier can travel for 1/(2F) seconds is a maximum of 50/F μm. Therefore, according to the embodiment, the short side length of the diffusion region 220 and the short side length of the non-diffusion region 240 are set to ½ of the distance in which the above-mentioned carriers can travel, that is, equal to or less than 25/F μm. Thereby, it is possible to increase the probability of the carriers being confined by a potential barrier between the diffusion region 220 and the non-diffusion region 240. Meanwhile, the setting of the lengths to ½ of the distance in which the carriers can travel is because the carriers can be sufficiently confined even when the distance in which the carriers can travel is set to equal to or less than ½, as the above-mentioned confining effect.

For example, when the frequency F of the high frequency signal applied to the semiconductor device 10 is set to 1 (GHz), the distance in which the carriers can travel is 50 μm. At this time, the short side length of the diffusion region 220 and the short side length of the non-diffusion region 240 are preferably equal to or less than 25 μm. Specifically, the short side length of the diffusion region 220 and the short side length of the non-diffusion region 240 are, for example, 1.5 μm. Thereby, the lengths are set to be shorter than ½ of the distance in which the carriers can travel, and thus it is possible to confine the carriers. That is, it is possible to substantially increase the resistivity of the silicon substrate 100.

In addition, the dose amount of the acceptors in the diffusion region 220 is designed on the basis of an areal average value of the areal density of the acceptors in the diffusion region 220 and the non-diffusion region 240. Here, when the first insulating layer 300 is a silicon oxide film, the areal density of the interfacial electrons in the vicinity of the surface of the silicon substrate 100 is typically approximately between 5×10¹⁰ cm⁻² to 1×10¹¹ cm⁻², inclusive. Therefore, the areal average value of the areal density of the acceptors obtained by summing up the diffusion region 220 and the non-diffusion region 240 is appropriately equal to or more than 1×10¹⁰ cm⁻² and equal to or less than 1×10¹² cm⁻².

Meanwhile, when the dose amount of the acceptors in the diffusion region 220 is increased so that the areal average value of the areal density of the acceptors becomes equal to or more than 1×10¹² cm⁻², the holes of the diffusion region 220 increase, and thus penetrate to the non-diffusion region 240. In this case, hole conduction occurs in the entirety including the non-diffusion region 240, effective resistivity in the interface direction decreases.

On the other hand, when the dose amount of the acceptors in the diffusion region 220 is decreased so that the areal average value of the areal density of the acceptors becomes equal to or less than 1×10¹⁰ cm ⁻², it is not possible to compensate for interfacial electrons present in the silicon substrate 100, and electronic conduction is dominant even in the diffusion region 220.

On the other hand, in the first embodiment, the areal average value of the areal density of the acceptors is equal to or more than 1×10¹⁰ cm⁻² and equal to or less than 1×10¹² cm⁻². By setting the value to the above-mentioned range, it is possible to prevent the holes from penetrating into the non-diffusion region 240 due to the excessively high dose amount of the acceptors in the diffusion region 220. In addition, it is possible to prevent the compensation for the interfacial electrons present in the silicon substrate 100 from being insufficient due to the excessively low dose amount of the acceptors in the diffusion region 220. In other words, it is possible to compensate for the interfacial electrons with an average of the diffusion region 220 and the non-diffusion region 240.

Here, the area ratio of the diffusion region 220 to the non-diffusion region 240 is considered so that the areal average value of the areal density of the acceptors mentioned above is satisfied, and the dose amount of the acceptors in the diffusion region 220 is determined. In the case of FIG. 1(b), the area ratio of the diffusion on 220 to the non-diffusion region 240 is, for example, 46:54. In addition, the dose amount of the acceptors in the diffusion region 220 is, for example, 1.4×10¹¹ cm⁻². Thereby, the areal average acceptor density of the diffusion region 220 and the non-diffusion region 240 becomes 6.4×10¹⁰ cm⁻², and is close to the areal density of the interfacial electrons in the vicinity of the surface of the silicon substrate 100. Therefore, it is possible to compensate for the interfacial electrons with the entire region of both the diffusion region 220 and the non-diffusion region 240.

As stated above, the interfacial electrons are compensated for in the vicinity of the surface of the silicon substrate 100, and thus it is possible to increase effective resistivity. Specifically, the resistivity of the region of both the diffusion region 220 and the non-diffusion region 240 in the silicon substrate 100 is equal to or more than 300Ωcm.

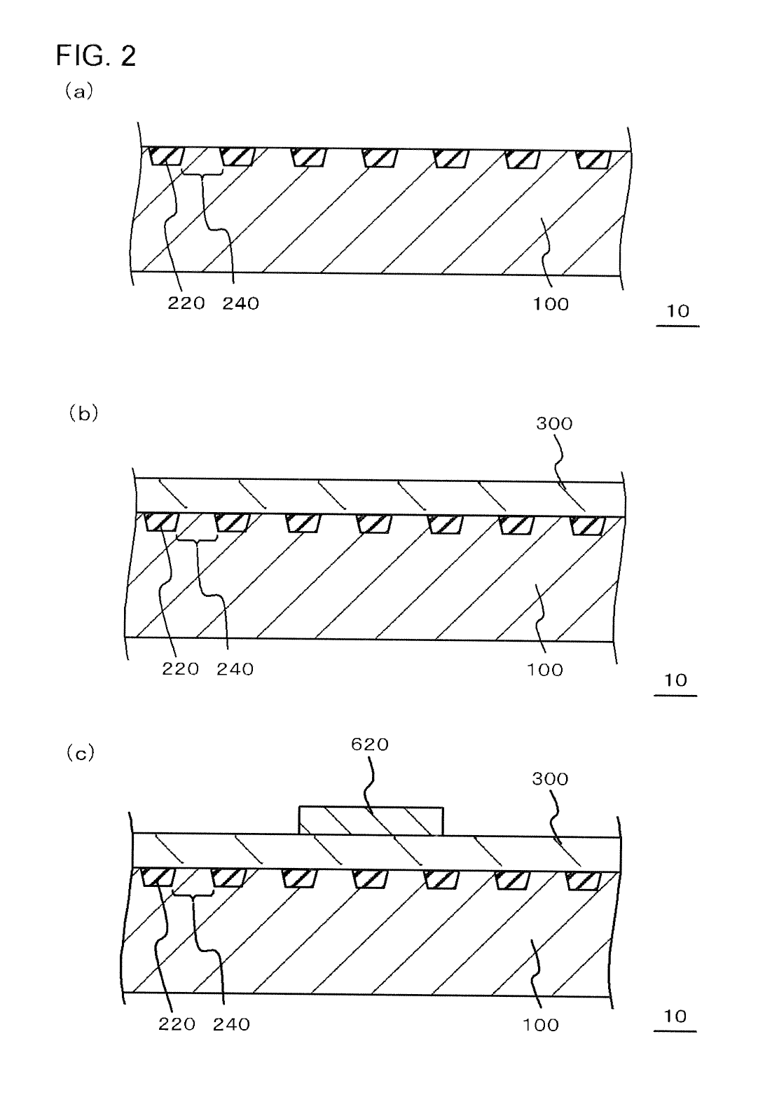

Next, a method of manufacturing the semiconductor device according to the first embodiment will be described with reference to FIG. 2. FIG. 2 is a cross-sectional view illustrating a method of manufacturing the semiconductor device according to the first embodiment. The method of manufacturing the semiconductor device 10 according to the first embodiment includes the following processes. First, the first insulating layer 300 is formed on the silicon substrate 100, and the diffusion region 220 into which the acceptors are introduced and the non-diffusion region 240 which is disposed alternately with the diffusion region 220 and into which the acceptors are not introduced are formed in the silicon substrate 100 (hereinafter, referred to as a “first process”). Next, the interconnect 620 is formed on the first insulating layer 300. Hereinafter, a detailed description will be given.

As shown in FIG. 2(a), first, the acceptors are introduced into a region serving as the diffusion region 220 in the silicon substrate 100. The introduction of the acceptors is performed by, for example, an ion implantation. At this time, in the ion implantation, a method of scanning only the region serving as the diffusion region 220 with the ion beam itself is used. Alternatively, a method may be used in which a resist film (not shown in the drawings) having an opening directly above the diffusion region 220 is patterned on the silicon substrate 100, and the ion implantation is performed. The acceptor is, for example, B (boron).

Here, the diffusion region 220 into which the acceptors are introduced and the non-diffusion region 240 which is disposed alternately with the diffusion region 220 and into which the acceptors are not introduced are formed in the silicon substrate 100.

Next, as shown in FIG. 2(b), the first insulating layer 300 is formed on the silicon substrate 100 in which the diffusion region 220 is formed. At this time, the first insulating layer 300 is, for example, a silicon oxide film. The first insulating layer 300 is formed by, for example, a thermal oxidation. Alternatively, the first insulating layer 300 is deposited by a chemical vapor deposition (CVD) method.

Next, heat treatment is performed in order to activate the introduced acceptors. The heat treatment is performed by, for example, lamp annealing or the like. An ion implantation region for forming the diffusion region 220 is designed in consideration of thermal diffusion with this heat treatment.

Next, as shown in FIG. 2(c), the interconnect 620 is formed on the first insulating layer 300. The interconnect 620 is, for example, Cu or Al. The interconnect 620 is formed by the following procedure. First, a resist film (not shown in the drawings) is applied onto the interconnect 620, and is patterned by lithographic exposure and development. Next, the interconnect 620 is etched. Next, the resist film is removed. Thereby, the interconnect 620 is obtained.

It is possible to obtain the semiconductor device 10 of the first embodiment through the above-mentioned processes.

Next, the effect of the first embodiment will be described in contradistinction to a comparative example.

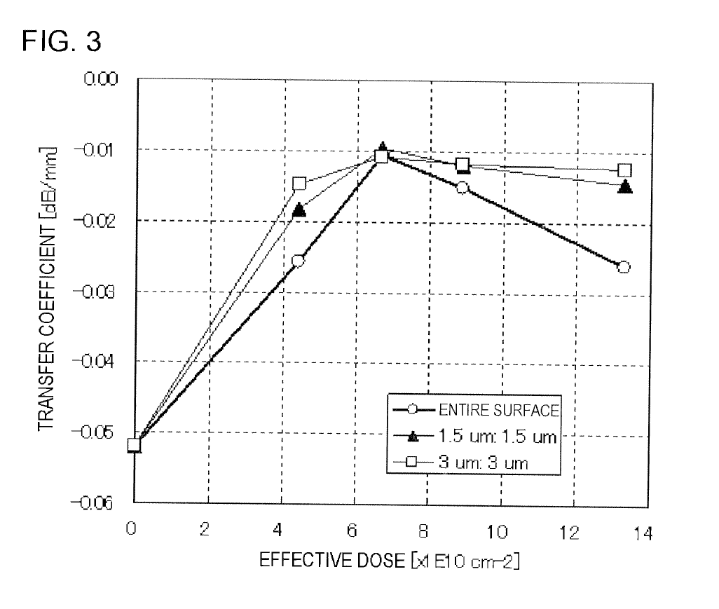

FIG. 3 is a diagram illustrating the effect of the first embodiment. The horizontal axis of FIG. 3 is an areal average value (“effective dose amount” in FIG. 3) of the areal density of the acceptors in the region into which the acceptors are introduced in the silicon substrate 100. In addition, the vertical axis of FIG. 3 is a transfer coefficient when a high frequency signal of 1 GHz is applied to the interconnect 620.

FIG. 3 shows results of a two-dimensional device simulation in three cases. Here, white circles show a case where the acceptors are introduced into the entire surface of silicon substrate 100, as the comparative example. In addition, black up-pointing triangles show a case where the width of the diffusion region 220 is 1.5 μm and the width of the non-diffusion region 240 is 1.5 μm, as the example according to the first embodiment. In addition, white squares show a case where the width of the diffusion region 220 is 3 μm and the width of the non-diffusion region 240 is 3 μm, as the example according to the first embodiment.

In any of the results, the transfer coefficient becomes the maximum when the areal average value (effective dose amount) of the areal density of the acceptors is 6.4×10 ¹⁰ cm⁻². This shows that it is possible to compensate for the interfacial electrons optimally in a case of such a dose amount.

In the comparative example, it is known that the transfer coefficient decreases considerably when the areal average value of the areal density of the acceptors deviates from this optimum value. When the areal average value of the areal density of the acceptors is smaller than the optimum value, the interfacial electrons are present and a transmission loss increases. On the other hand, when the areal average value of the areal density of the acceptors is larger than the optimum value, the interfacial electrons are compensated, but the excess of acceptors brings holes and a transmission loss increases.

Meanwhile, in the actual silicon substrate 100, it is expected that a variation in the interfacial electron density occurs for each wafer or in the plane of the wafer. However, evaluating the interfacial electron density in advance is difficult because the mass productivity of the semiconductor device is significantly impaired. Therefore, in the comparative example, a constant dose amount is introduced into the entire surface of the wafer, without regard for a variation in the interfacial electron density. In such a case, as in the comparative example, when the acceptors are introduced into the entire surface of the silicon substrate 100, any one of the interface carriers as mentioned above is generated in a wafer or a portion of a wafer either of which is out of tune with the interfacial electron density, which leads to a transmission loss.

In addition, as in the comparative example, when the acceptors are introduced into the entire surface of the silicon substrate 100, it is also expected that the implanted acceptor dose itself may be varied. Similarly, in such a case, any one of the interface carriers is generated in the portion out of tune with the interfacial electron density, which leads to a transmission loss.

In this manner, as in the comparative example, when the acceptors are introduced into the entire surface of the silicon substrate 100, stable high-frequency characteristics may not be obtained.

On the other hand, in the two examples according to the first embodiment, even when the areal average value of the areal density of the acceptors deviates from the optimum value, the transfer coefficient shows a higher value than that in the comparative example.

In the two examples according to the first embodiment, the diffusion region 220 into which the acceptors are introduced and the non-diffusion region 240 into which the acceptors are not introduced are alternately disposed in the silicon substrate 100. Here, in the vicinity of the surface of the silicon substrate 100, the diffusion region 220 into which the acceptors are introduced serves as a p-type region. On the other hand, the non-diffusion region 240 into which the acceptors are not introduced serves as an n-type region due to the interfacial electrons. In this manner, the p-type region and the n-type region are alternately disposed. Thereby, electrons and holes generated in the vicinity of the surface of the silicon substrate 100 are confined by a mutual potential barrier. Therefore, it is possible to effectively increase the resistivity of the silicon substrate 100. In addition, when the interfacial electron density varies in the plane, it is possible to reduce the influence thereof. From the above-mentioned reason, in the two examples according to the first embodiment, it is considered that the transfer coefficient shows a higher value than that in the comparative example even when the areal average value of the areal density of the acceptors deviates from the optimum value.

As stated above, when a high frequency is applied, it is possible to suppress the influence of the carriers generated in the vicinity of the surface of the silicon substrate 100.

(Second Embodiment)

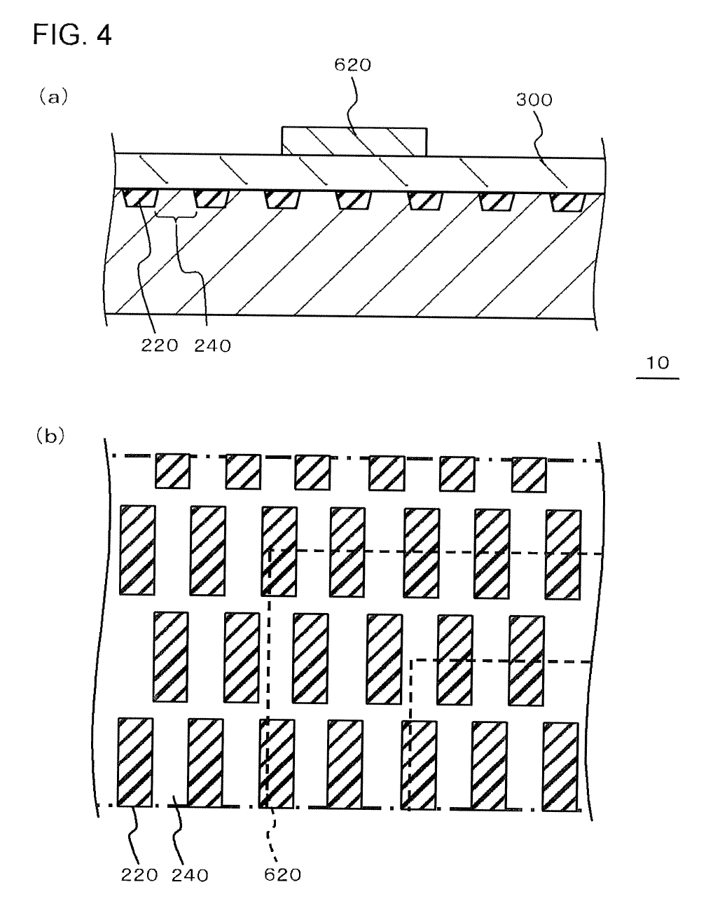

FIG. 4 is a diagram illustrating a configuration of a semiconductor device according to a second embodiment. Meanwhile, FIG. 4(a) is a cross-sectional view illustrating a configuration of the semiconductor device 10. In addition, FIG. 4(b) is a plan view in the vicinity of the surface of the silicon substrate 100. The second embodiment is the same as the first embodiment except for the following point. Either the diffusion region 220 or the non-diffusion region 240 is disposed in an island shape in a region in which the interconnect 620 is bent. Hereinafter, a detailed description will be given.

As shown in FIG. 4(a), the configuration of the cross section of the semiconductor device 10 is the same as that in the first embodiment.

As shown in FIG. 4(b), the interconnect 620 is bent in an L shape within the region shown in the drawing. Here, the frequency F (GHz) of a high frequency signal applied to the interconnect 620 is, for example, equal to or more than 0.1 (GHz). For this reason, when the high frequency signal is applied to the interconnect 620, an electric field is generated in the vicinity of the surface of the silicon substrate 100, in two directions in the interface direction (vertical direction and horizontal direction in FIG. 4(b)) which are at right angles to each other, when seen in a plan view.

In this region, the diffusion region 220 is disposed, for example, in a quadrangular island shape. Thereby, in the vicinity of the surface of the silicon substrate 100, even when an electric field is generated in the above-mentioned two directions, it is possible to suppress the interface carrier transport in each of the directions. Therefore, it is possible to effectively increase the resistivity in the interface direction.

Here, in a photolithography process, the minimum size of a mask pattern is specified, and such a pattern that island portions of the diffusion regions 220 are brought into contact with each other in the corner is not permitted. Therefore, the island portions of the diffusion regions 220 are separated from each other in the vicinity of the corner. The distance by which the island portions are separated from each other in the vicinity of the corner is preferably a distance of the minimum size capable of being designed. Thereby, it is possible to minimize the interfacial electron transport in the non-diffusion region 240 through this gap.

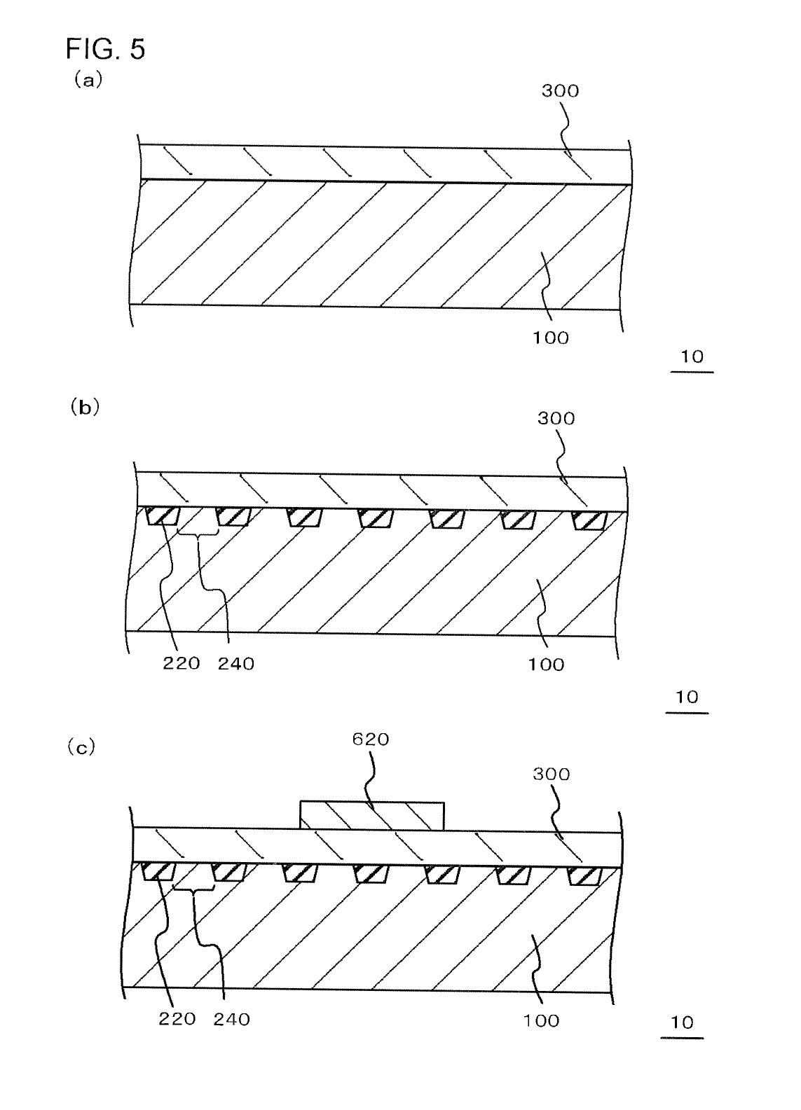

Next, a method of manufacturing the semiconductor device according to the second embodiment will be described with reference to FIG. 5. FIG. 5 is a cross-sectional view illustrating a method of manufacturing the semiconductor device according to the second embodiment. The manufacturing method of the second embodiment is the same as the manufacturing method of the first embodiment, except that in the first process, the first insulating layer 300 is formed, and then the diffusion region 220 is formed by introducing the acceptors into the silicon substrate 100 through the first insulating layer 300. Hereinafter, a detailed description will be given.

As shown in FIG. 5(a), first, in the first process, the first insulating layer 300 is formed on the silicon substrate 100 in which the diffusion region 220 is not formed, unlike the first embodiment.

Next, as shown in FIG. 5(b), in the first process, the first insulating layer 300 is formed, and then the diffusion region 220 is formed by introducing the acceptors into the silicon substrate 100 through the first insulating layer 300. At this time, the acceptors are introduced so that the diffusion region 220 is formed in an island shape.

Meanwhile, when an ion implantation is used in the introduction of the acceptors, an acceleration voltage is adjusted so that the diffusion region 220 is formed in the vicinity of the surface of the silicon substrate 100.

Next, heat treatment is performed in order to activate the introduced acceptors. The heat treatment is the same as that in the first embodiment.

Next, as shown in FIG. 5(c), the interconnect 620 is formed on the first insulating layer 300. It is possible to obtain the semiconductor device 10 through the above-mentioned processes.

According to the second embodiment, either the diffusion region 220 or the non-diffusion region 240 is disposed in an island shape in a region in which the interconnect 620 is bent. In the region in which the interconnect 620 is bent, when a high frequency signal is applied to the interconnect 620, an electric field in the interface direction in the vicinity of the surface of the silicon substrate 100 is generated in directions perpendicular to each of the directions of the interconnect 620 on the front side and the backside of the bending point. For this reason, it is possible to suppress the interface carrier transport in each of the directions of the interconnect 620 on the front side and the back side of the bending point by disposing either the diffusion region 220 or the non-diffusion region 240 in an island shape, even when the electric field is generated as described manner. Therefore, in this case, it is also possible to effectively increase the resistivity of the silicon substrate 100.

According to the manufacturing method of the second embodiment, the first insulating layer 300 is formed in advance, and then the diffusion region 220 is formed by introducing the acceptors into the silicon substrate 100 through the first insulating layer 300. Thereby, the position of the diffusion region 220 can be adjusted in accordance with the pattern of the first insulating layer 300 formed in advance. In addition, the heat treatment for the activation of the acceptors is performed after the first insulating layer 300 is formed. Thereby, the acceptors are not diffused excessively.

Meanwhile, the configuration of the first embodiment may be created by the manufacturing method of the second embodiment. Alternatively, the configuration of the second embodiment may be created by the manufacturing method of the first embodiment.

(Third Embodiment)

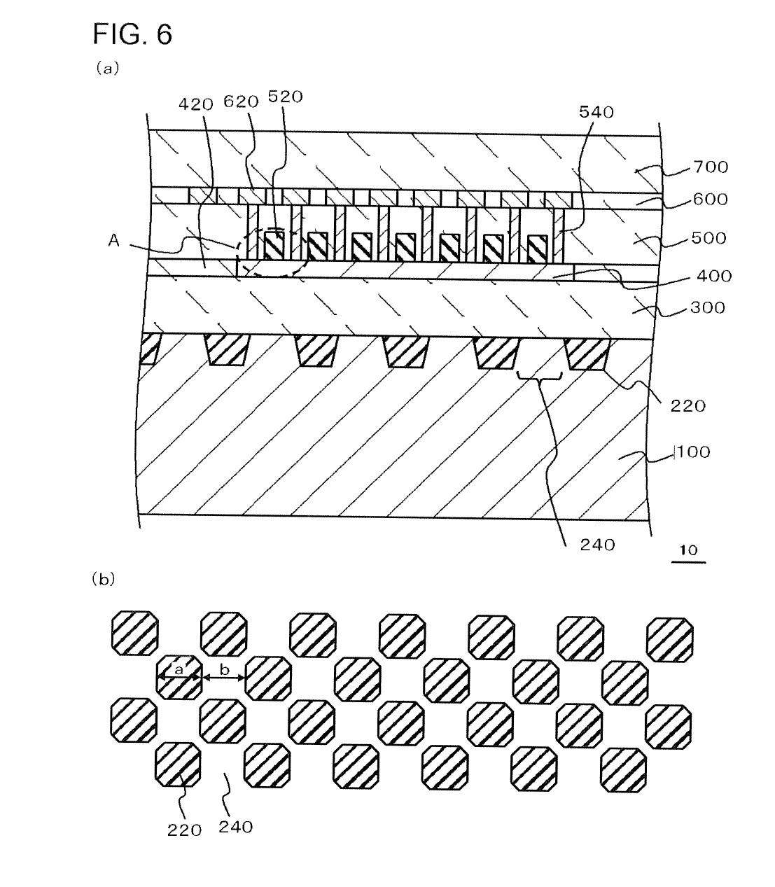

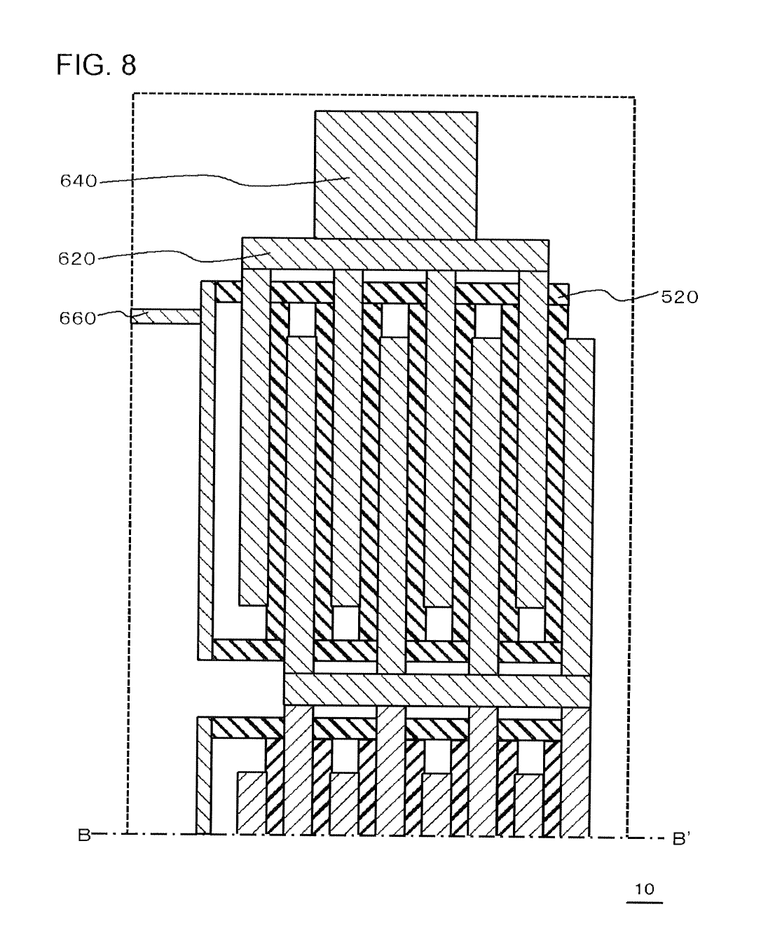

FIG. 6 is a diagram illustrating a configuration of a semiconductor device 10 according to a third embodiment. Meanwhile, FIG. 6(a) is a cross-sectional view illustrating a configuration of the semiconductor device 10. In addition, FIG. 6(b) is a plan view in the vicinity the surface of the silicon substrate 100. In addition, FIG. 6(a) is a cross-sectional view taken along line B-B′ FIG. 8 described later.

The third embodiment is the same as the second embodiment, except for the following point. The semiconductor device includes the following configuration in addition to the second embodiment. A silicon layer 400 is provided so as to contact with the top of the first insulating layer 300. In addition, an element isolation region 420 is provided in the silicon layer 400. Further, a semiconductor element (40) is provided in the silicon layer 400. In addition, an insulating interlayer 500 is provided on the silicon layer 400, the element isolation region 420 and the semiconductor element (40). In addition, vias 540 are provided in the insulating interlayer 500. Further, the interconnects 620 are provided on the insulating interlayer 500, and are connected to the semiconductor elements (40) through the vias 540. Hereinafter, a detailed description will be given.

As shown in FIG. 6(a), similarly to the first embodiment, the diffusion region 220 is provided in the silicon substrate 100. In addition, the diffusion region 220 and the non-diffusion region 240 are alternately disposed. The length a of the island portion of the diffusion region 220 is, for example, 1.5 μm. In addition, the length b of the non-diffusion region is also, for example, 1.5 μm.

As shown in FIG. 6(b), the diffusion region 220 is disposed in an island shape. Further, each island portion of the diffusion region 220 is, for example, octagonal. In this case, the islands of the diffusion region 220 are also separated from each other in the vicinity of the corner having a short side in the octagon. In addition, the distance by which the island portions are separated from each other in the vicinity of the corner is equal to a distance of the minimum size capable of being designed. Thereby, there is a low possibility that the interfacial electrons in the non-diffusion region 240 are transported through this gap.

As shown in FIG. 6(a), the first insulating layer 300 is provided so as to contact with the top of the silicon substrate 100. The first insulating layer 300 is, for example, a silicon oxide film.

In addition, the silicon layer 400 is provided so as to contact with the top of the first insulating layer 300. The silicon layer 400 is a so-called silicon on insulator (SOI) layer. Therefore, the above-mentioned first insulating layer 300 is a buried oxide (BOX) layer. The detailed description of a process for forming the silicon layer 400 will be given later.

In addition, the element isolation region 420 having an opening is provided in the silicon layer 400. The element isolation region 420 is, for example, a shallow trench isolation (STI). Here, the element isolation region 420 is a region in which an opening is formed by removing the silicon layer 400 once, and then is buried with an insulating layer. In addition, the element isolation region 420 is, for example, a silicon oxide film.

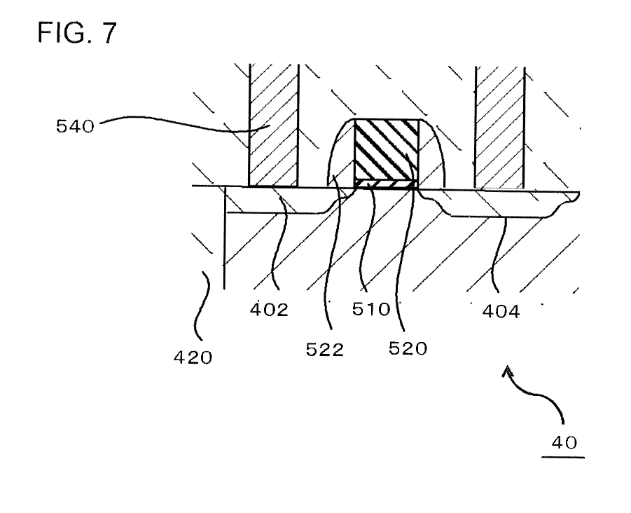

FIG. 7 is an enlarged cross-sectional view of a portion A in FIG. 6. As shown in FIG. 7, a semiconductor element 40 is provided in the silicon layer 400. The semiconductor element 40 is formed in a portion in which the element isolation region 420 is not formed. Meanwhile, the semiconductor element 40 is for example, a field effect transistor (FET).

The semiconductor element 40 includes, for example, the following configuration. A source region 402 and a drain region 404 are provided in the vicinity in the interface of the silicon layer 400 on the insulating interlayer 500 side. A channel region (not shown) is formed between these regions. A gate insulating film 510 and a gate electrode 520 are provided on the channel region in the silicon layer 400. A sidewall insulating film 522 is provided at sidewalls on both sides of the gate insulating film 510 and the gate electrode 520.

In addition, as shown in FIG. 6(a), the insulating interlayer 500 is provided on the silicon layer 400, the element isolation region 420 and the semiconductor element (40). The insulating interlayer 500 is, for example, a silicon oxide film.

Meanwhile, the insulating interlayer 500 may consist of plural layers. A liner insulating film (not shown in the drawings) located below the insulating interlayer 500 in FIG. 6(a) may be included on the silicon layer 400, the element isolation region 420 and the semiconductor element (40). Alternatively, an etching stopper film (not shown in the drawings) may be included between an insulating interlayer 600 described later and the insulating interlayer 500. The liner insulating film or the etching stopper film is, for example, a silicon nitride film having etching selectivity from a silicon oxide film.

In addition, the insulating interlayer 500 maybe formed with the same composition as that of the element isolation region 420. Further, an interface may not be formed between the insulating interlayer 500 and the element isolation region 420.

In addition, the vias 540 are provided in the insulating interlayer 500. Further, the interconnects 620 are provided on the insulating interlayer 500. The interconnects 620 are connected to the above-mentioned semiconductor elements 40 through the vias 540. Here, the via 540 is connected to, for example, the source region 402 or the drain region 404 in the semiconductor element 40. In addition, in a region which is not shown in FIG. 6(a), the via 540 is connected to the gate electrode 520.

The insulating interlayer 600 is further provided in regions other than the interconnect 620. In addition, an insulating interlayer 700 is provided on the insulating interlayer 600 and the interconnect 620. Meanwhile, in a region which is not shown in FIG. 6(a), a via (not shown in the drawings) or an interconnect (not shown in the drawings) connected to the interconnect 620 may be provided.

FIG. 8 is a plan view illustrating a configuration of the semiconductor device 10 according to the third embodiment. FIG. 8 schematically shows only the interconnects in each layer. As shown in FIG. 8, the semiconductor device 10 is a single pole single throw (SPST) switching circuit. In addition, the interconnect 620 connected to the source region 402 of the semiconductor element 40 and the interconnect 620 connected to the drain region 404 are alternately disposed in a comb shape. In addition, a gate interconnect 660 connected to the gate electrode 520 is provided in a region which does not overlap the interconnect 620 connected to the source region 402 or the drain region 404, mentioned above, when seen in a plan view. In addition, an electrode pad 640 connected to the interconnect 620 is provided in the uppermost layer of a multilayer structure shown in FIG. 6(a).

In addition, the interconnect 620 to which a high frequency signal is applied or the semiconductor element (40) is formed in a region within the dotted line of FIG. 8 when seen in a plan view. In at least the region, the diffusion region 220 and the non-diffusion region 240 are formed so as to be alternately disposed. Thereby, it is possible to effectively increase the resistivity of the silicon substrate 100 in the region in which the interconnect 620 or the semiconductor element (40) is provided.

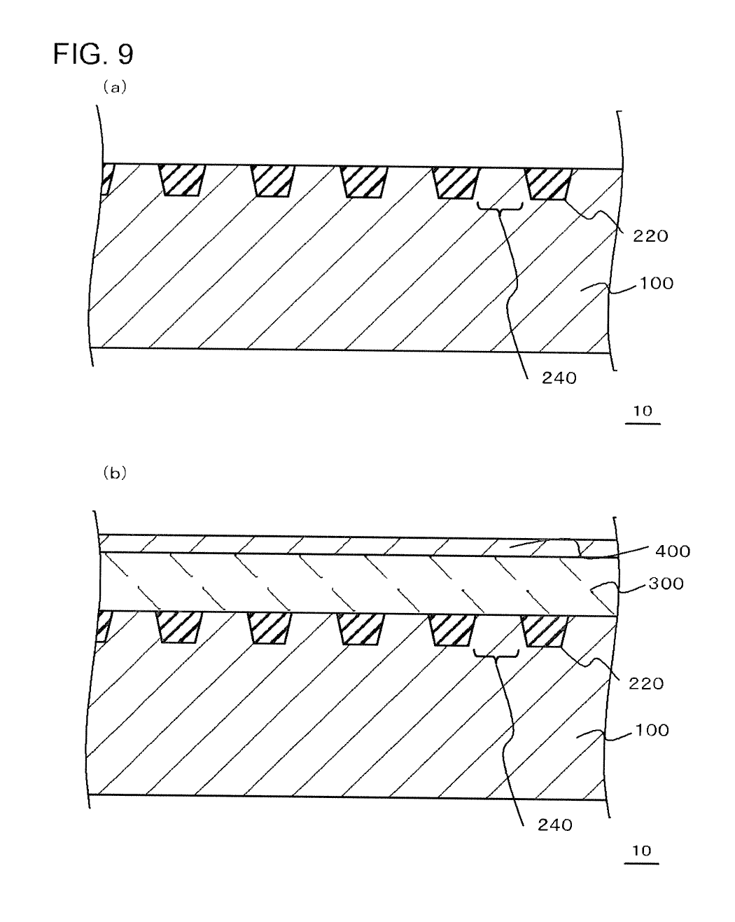

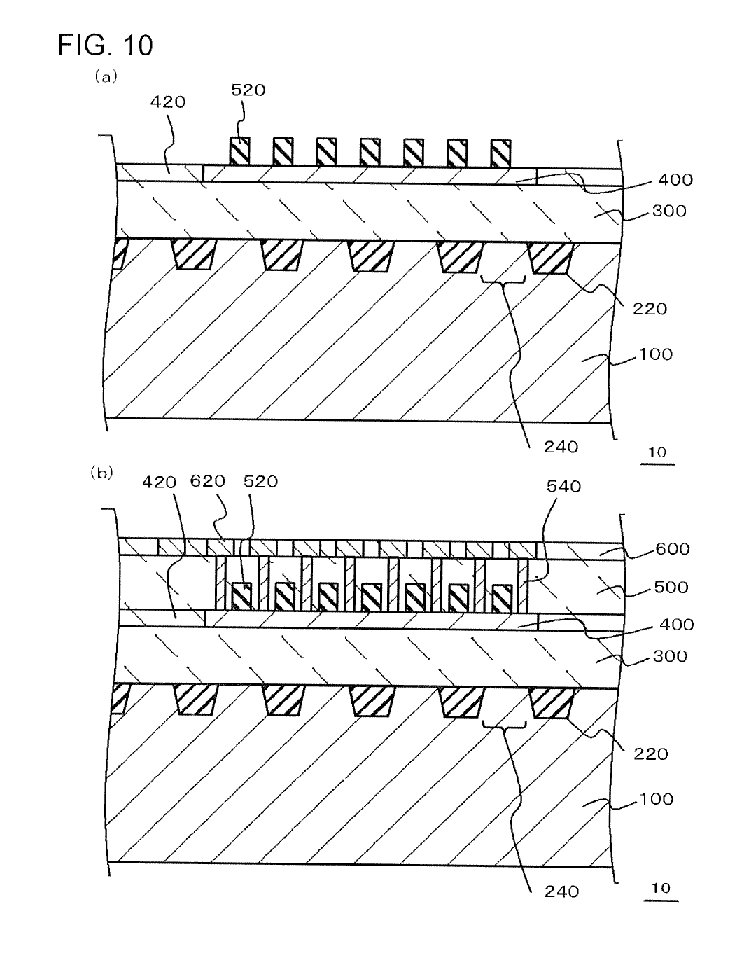

Next, a method of manufacturing the semiconductor device according to the third embodiment will be described with reference to FIGS. 9 and 10. FIGS. 9 and 10 are cross-sectional views illustrating a method of manufacturing the semiconductor device according to the third embodiment. The manufacturing method of the third embodiment includes the following processes in addition to the processes of the first embodiment. In the first process, the silicon layer 400 is formed so as to contact with the top of the first insulating layer 300. Further, the element isolation region 420 having an opening is form in the silicon layer 400. Next, the semiconductor element (40) is formed in a portion located within the opening of the element isolation region 420 in the silicon layer 400. Next, the insulating interlayer 500 is formed on the silicon layer 400, the element isolation region 420 and the semiconductor element (40). Next, the vias 540 are formed in the insulating interlayer 500. Next, the interconnects 620 are formed on the insulating interlayer 500 so as to be connected to the semiconductor elements (40) through the vias 540. Hereinafter, a detailed description will be given.

First, as shown in FIG. 9(a), the acceptors are introduced into a region serving as the diffusion region 220 in the silicon substrate 100. Here, the diffusion region 220 into which the acceptors are introduced and the non-diffusion region 240 which is disposed alternately with the diffusion region 220 and into which the acceptors are not introduced are formed in the silicon substrate 100.

Next, a bonding silicon substrate (400) on which the first insulating layer 300 serving as a BOX layer on the substrate surface is formed is prepared. Next, H⁺ ions are implanted into a portion serving as the surface side of the silicon layer 400, described later, in the bonding silicon substrate (400).

Next, as shown in FIG. 9(b), the bonding silicon substrate (400) is attached onto the silicon substrate 100. Next, the two bonded substrates are bonded to each other by heat treatment at a high temperature. Next, the bonding silicon substrate (400) is peeled off from the interface into which the previous H⁺ ions are implanted, and the silicon layer 400 is formed. Meanwhile, not only a method that implants the above-mentioned H⁺ ions, but also a method that grinds the bonding silicon substrate (400) may be used.

Next, heat treatment is performed in order to activate the introduced acceptors. The heat treatment is performed by, for example, lamp annealing or the like.

Next, as shown in FIG. 10(a), the element isolation region 420 is formed in the silicon layer 400. As the element isolation region 420, for example, an STI is formed.

Next, the semiconductor element (40) is formed in the silicon layer 400. The semiconductor element (40) is formed through the following processes, in a case of such a configuration as that in FIG. 7. As shown in FIG. 7, first, the gate insulating film 510 and the gate electrode 520 are formed on the silicon layer 400. Next, extension regions (not shown in the drawings) of the source region 402 and the drain region 404 are formed by implanting impurity ions, using the gate insulating film 510 and the gate electrode 520 as a mask. Next, the sidewall insulating film 522 is formed at sidewalls on both sides of the gate insulating film 510 and the gate electrode 520. Next, an ion implantation is performed using the gate electrode 520 and the sidewall insulating film 522 as a mask, and the source region 402 and the drain region 404 are formed through activation annealing. The semiconductor element 40 is formed through the above-mentioned processes.

Next, as shown in FIG. 10(b), the insulating interlayer 500 is formed on the silicon layer 400, the element isolation region 420 and the semiconductor element (40). As the insulating interlayer 500, for example, a silicon oxide film is formed by a CVD. Meanwhile, the insulating interlayer 500 may consist of plural layers. At this time, a liner insulating film (not shown in the drawings) may be formed on the silicon layer 400, the element isolation region 420 and the semiconductor element (40).

Next, a via hole (not shown in the drawings) is formed in the insulating interlayer 500 by dry etching so as to be connected to the gate electrode 520, the source region (402) or the drain region (404) of the semiconductor element (40). Next, the inside of the via hole is buried with a conductive material by a plating method. Thereby, the via 540 connected to the gate electrode 520, the source region (402) or the drain region (404) is formed. The conductive material is, for example, Cu.

Next, the above-mentioned conductive material and the insulating interlayer 500 are planarized by chemical mechanical polishing (CMP).

Next, the insulating interlayer 600 and the interconnect 620 are formed by the same method as forming the via 540 mentioned above. Meanwhile, the interconnect 620 may be formed by a dual damascene method by forming an etching stopper film (not shown in the drawings) between the insulating interlayer 600 and the insulating interlayer 500.

Next, the insulating interlayer 700 is formed on the insulating interlayer 600 and the interconnect 620. Meanwhile, a via (not shown in the drawings) or an interconnect (not shown in the drawings) connected to the interconnect 620 may be formed in a region which is not shown in FIG. 10(b).

According to the third embodiment, the silicon layer 400 which is an SOI layer is provided so as to contact with the top of the first insulating layer 300. In addition, the semiconductor element (40) is provided in a portion located within the opening of the element isolation region 420 in the silicon layer 400. In the region in which the semiconductor element (40) is formed, the diffusion region 220 and the non-diffusion region 240 are formed so as to be alternately disposed. In the region in which the semiconductor element (40) is formed, when a high frequency signal is applied to the interconnect 620, an electric field is generated in complicated directions, when seen in a plan view, in the interface direction in the vicinity of the surface of the silicon substrate 100. For this reason, it is possible to suppress the interface carrier transport in each direction by disposing the diffusion region 220 and the non-diffusion region 240, mentioned above, in the region in which the semiconductor element (40) is formed, even when an electric field is generated complicatedly. Therefore, it is possible to effectively increase the resistivity of the silicon substrate 100.

(Fourth Embodiment)

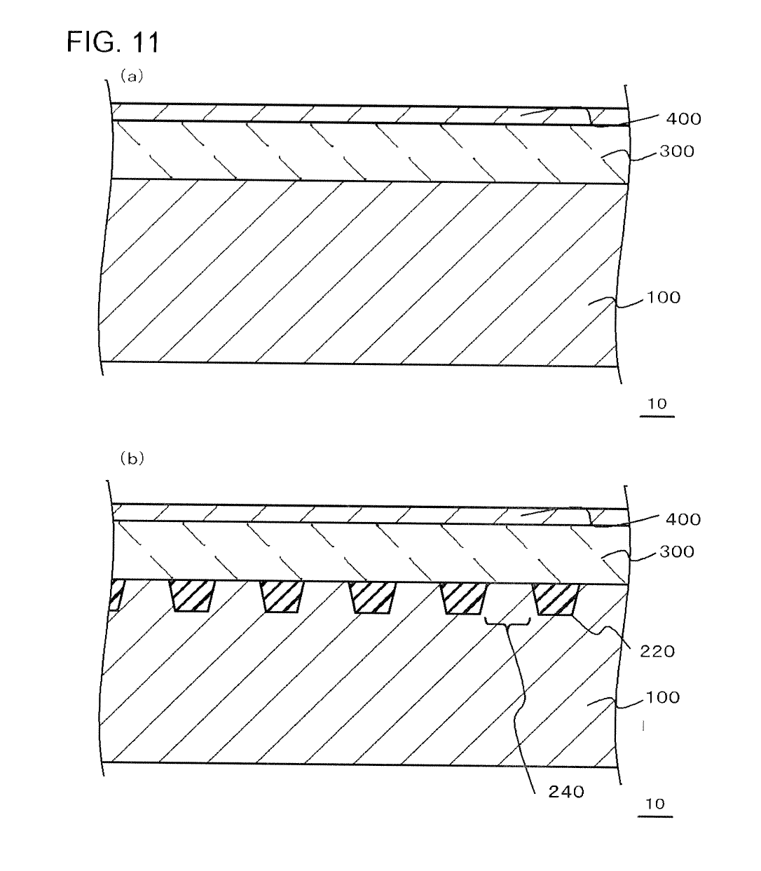

Next, a method of manufacturing a semiconductor device 10 according to a fourth embodiment will be described with reference to FIG. 11. FIG. 11 is a cross-sectional view illustrating a method of manufacturing the semiconductor device 10 according to the fourth embodiment. The fourth embodiment is the same as the third embodiment, except that in the first process, the silicon layer 400 is formed, and then the diffusion region 220 is formed by introducing the acceptors into the silicon substrate 100 through the silicon layer 400 and the first insulating layer 300.

As shown in FIG. 11(a), an SOI substrate may be formed by a separation-by-implanted-oxygen (SIMOX) method. First, high concentration oxygen ions are implanted into the silicon substrate 100, and then the first insulating layer 300 (BOX layer) is formed by performing high temperature annealing. At this time, simultaneously, the silicon layer 400 is formed by restoring crystallinity.

Next, as shown in FIG. 11(b), the silicon layer 400 is formed, and then the diffusion region 220 is formed by introducing the acceptors into the silicon substrate 100 through the silicon layer 400 and the first insulating layer 300. The following processes are the same as those in the third embodiment.

According to the manufacturing method of the fourth embodiment, the SOI substrate including the first insulating layer 300 and the silicon layer 400 is formed in advance, and then the diffusion region 220 is formed by introducing the acceptors into the silicon substrate 100 through the silicon layer 400 and the first insulating layer 300. In such a method, heat treatment for the activation of the acceptors is performed after the SOI substrate including the first insulating layer 300 and the silicon layer 400 is formed. Thereby, the acceptors are not diffused excessively by the heat treatment for the formation of the SOI substrate.

Meanwhile, the SOI substrate of FIG. 9(b) in the third embodiment or FIG. 11(b) in the fourth embodiment can be traded in the form of transaction which is supplied to a semiconductor maker.

As stated above, in the third and fourth embodiments, the different methods for forming the silicon layer 400 (methods for forming the SOI substrate) are respectively used, but the other method may be used in any of the embodiments.

(Fifth Embodiment)

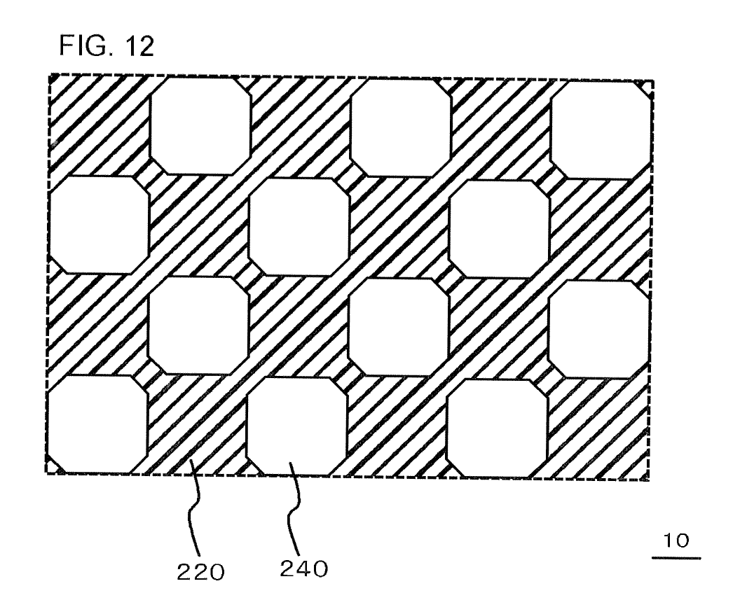

Next, a semiconductor device 10 according to a fifth embodiment will be described with reference to FIGS. 12 to 15. FIGS. 12 to 15 are plan views illustrating configurations of the semiconductor device according to the fifth embodiment. The above-mentioned embodiment is the same as that in the first or third embodiment, except for the different arrangement of the diffusion regions 220.

For example, similarly to the first or third embodiment, the interconnect 620 which is a transmission line to which a high frequency signal is applied or the semiconductor element (40) is formed in regions within the dotted lines of FIGS. 12 to 15 when seen in a plan view. The diffusion region 220 is formed within the regions.

In the case of FIG. 12, the non-diffusion regions 240 are disposed within the diffusion region 220 in an island shape. The diffusion region 220 and the non-diffusion regions 240 are disposed so as to be opposite to those of FIG. 6(b) in the third embodiment. In this case, it is also possible to obtain the same effect as that in the third embodiment.

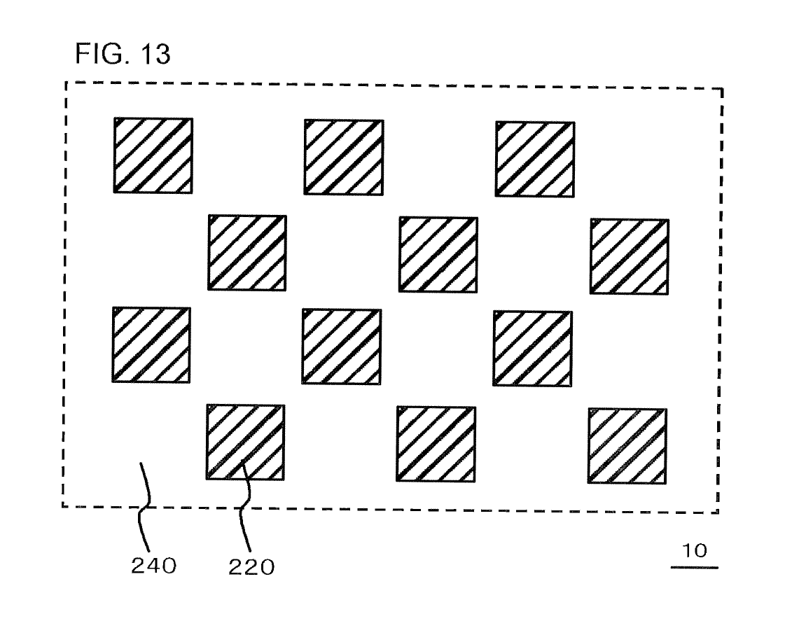

In the case of FIG. 13, the diffusion regions 220 are disposed in an island shape. However, these regions are formed so that the area occupied by the diffusion regions 220 becomes equal to or less than 50% of the formation region (inside of the dotted line). In such a case, the areal average value of the areal density of the acceptors in the diffusion regions 220 and the non-diffusion region 240 is set to be equal to or more than 1×10¹⁰ cm⁻² and equal to or less than 1×10¹² cm⁻², and thus the amount of the acceptors to be introduced into the diffusion regions 220 increases relatively. In this manner, the area ratio is appropriately adjusted, and thus the required amount of the acceptors to be introduced can be adjusted, for example, to a range capable of an ion implantation with higher dose accuracy.

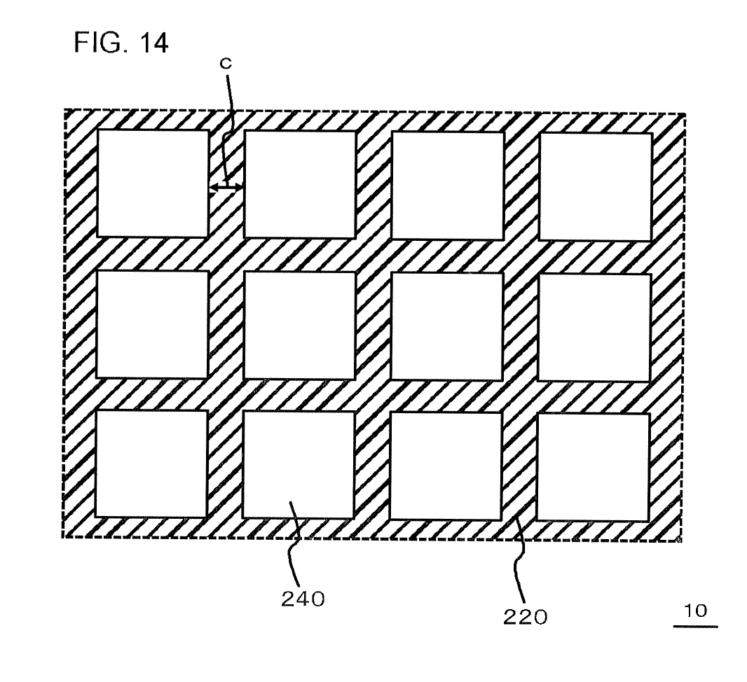

In the case of FIG. 14, the diffusion region 220 is formed so as to surround the non-diffusion regions 240. In this case, the mobility of electrons as carriers in the non-diffusion region 240 is higher than the mobility of holes as carriers in the diffusion region 220, and thus it is possible to suppress the conduction of electrons more reliably. At this time, the “length of the diffusion region 220 on the short side” as previously mentioned is a distance c in FIG. 14. The distance c is set to be equal to or less than 25/F μm.

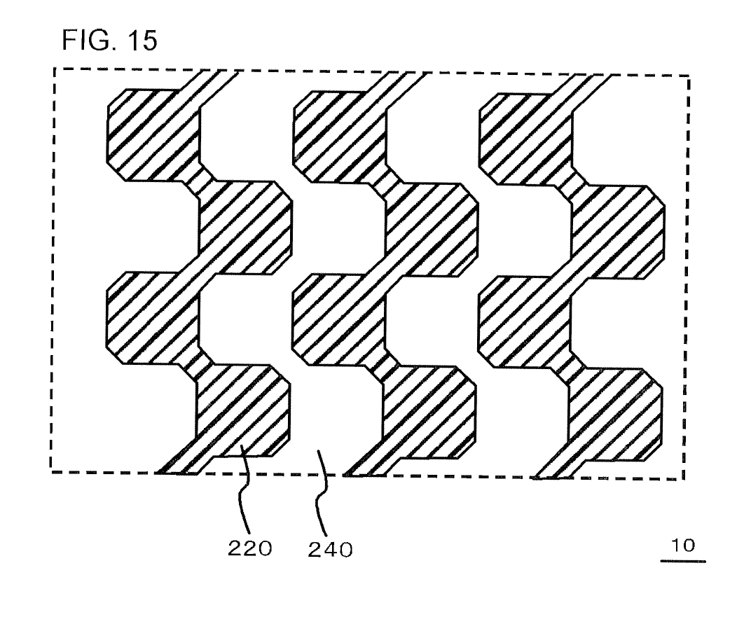

In the case of FIG. 15, the diffusion region 220 includes a plurality of island portions disposed separately from each other, and connection portions which have a smaller width than that of the island portion when seen in a plan view and are connected to the island portion. The connection portion connects two island portions adjacent to each other. In addition, the non-diffusion region 240 is separated by the diffusion region 220. Meanwhile, the width and length of the connection portion are preferably, for example, distances of the minimum size capable of being designed.

In this manner, the adjacent diffusion regions 220 are not connected to each other in directions perpendicular to directions in which the island portions of the diffusion region 220 are connected to each other and extend. Thereby, holes or electrons do not move in the directions.

In addition, the adjacent island portions of the diffusion region 220 are connected to each other by the connection portion at a distance of the minimum size capable of being designed. Thereby, it is also less likely that holes or electrons are transported in the directions in which the island portions of the diffusion region 220 are connected to each other and extend.

According to the case of FIG. 15, when the interconnect 620 or the semiconductor element (40) is intricately disposed, it is possible to particularly suppress the interface carrier transport. In addition, in the vicinity of the surface of the silicon substrate 100, it is possible to provide the directions in which the island portions of the diffusion region 220 are connected to each other and extend, in a direction in which a relatively strong electric field is generated.

According to the cases of FIGS. 12 to 15 in the fifth embodiment, it is possible to obtain the same effect as that in the first or third embodiment.

(Sixth Embodiment)

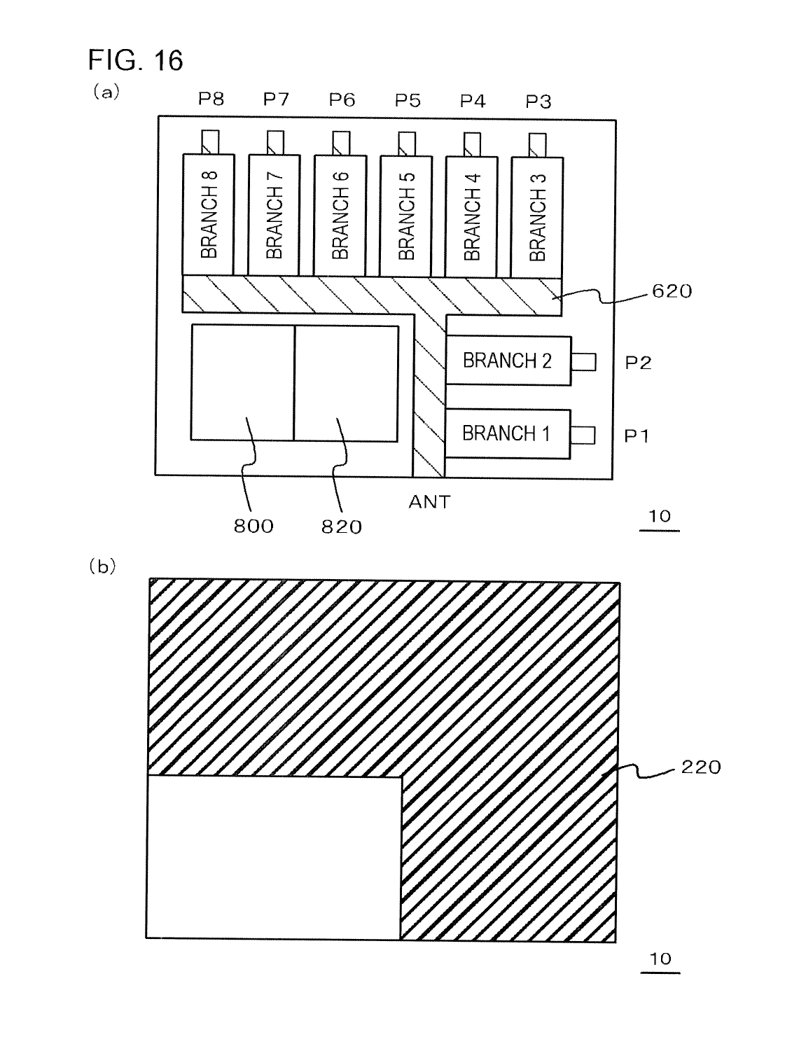

Next, a semiconductor device 10 according to a sixth embodiment will be described with reference to FIG. 16. FIG. 16 is a plan view illustrating a configuration of the semiconductor device according to the sixth embodiment. Meanwhile, FIG. 16(a) is a plan view illustrating a configuration of the semiconductor device 10. In addition, FIG. 16(b) shows a region in which the diffusion region 220 is formed in the semiconductor device 10. The sixth embodiment is the same as the first to fifth embodiments, except that a bias generation circuit 800 and a control circuit 820 are included in the semiconductor device 10.

As shown in FIG. 16(a), the semiconductor device 10 includes an SP8T switching circuit. A branch 1 to a branch 8 include the same cross-sectional configuration as that of the third embodiment. A high frequency signal passes between an ANT port and a port selected out of ports P1 to P8 through the interconnect 620.

In addition, the semiconductor device includes the bias generation circuit 800 that generate a power supply voltage and the control circuit 820 that controls a high frequency signal. In addition, the bias circuit 800 or the control circuit 820 is connected to the gate interconnect (660) in a layer which is not shown. The power supply voltage generated from the bias generation circuit 800 is supplied to a gate of the semiconductor element (40). In addition, the control circuit 820 is a logic circuit that controls a switch selection state of the high frequency signal in each branch by controlling a gate bias.

As shown in FIG. 16(b), the diffusion region 220 is formed in at least a region in which the branch 1 to the branch 8 are formed. Meanwhile, the region (hatched portion) in which the diffusion region 220 is formed may have any pattern of the above-mentioned embodiment, and is appropriately selected in accordance with a pattern such as the interconnect 620. However, the diffusion region 220 may be provided in a region in which the bias generation circuit 800 and the control circuit 820 are formed.

According to the sixth embodiment, it is possible to obtain the same effect as that in the first to fifth embodiments. In addition, it is possible to provide a stable high-frequency switching circuit having a small transmission loss.

In the above-mentioned embodiments, a case has been described in which the diffusion region 220 is provided in the region where the interconnect 620 which is a transmission line or the semiconductor element (40) is formed. Furthermore, a region in which a spiral inductor, a resistive element or a capacitive element is formed may be used.

In addition, in the above-mentioned embodiments, a case has been described in which the patterns of the region where the diffusion region 220 is provided are the same as each other within the region, but the above-mentioned patterns can also be combined within the same region.

As described above, although the embodiments of the invention have been set forth with reference to the drawings, they are merely illustrative of the invention, and various configurations other than those stated above can be adopted.

This application claims priority from Japanese Patent Application No. 2011-67013 filed on Mar. 25, 2011, the content of which is incorporated herein by reference in its entirety.

1. A semiconductor device comprising:
a diffusion region which is provided in a silicon substrate, and into which acceptors are introduced;
a non-diffusion region which is disposed in the silicon substrate alternately with the diffusion region, and into which the acceptors are not introduced;
a first insulating layer which is provided so as to contact with the silicon substrate; and
an interconnect which is provided over the first insulating layer.

2. The semiconductor device according to claim 1, further comprising:
a silicon layer which is provided so as to contact with the top of the first insulating layer;
an element isolation region which is provided in the silicon layer;
a semiconductor element which is provided in the silicon layer;
an insulating interlayer which is provided over the silicon layer, the element isolation region and the semiconductor element; and
a via which is provided in the insulating interlayer,
wherein the interconnect is provided over the insulating interlayer, and is connected to the semiconductor element through the via.

3. The semiconductor device according to claim 1, wherein when a frequency of a high frequency signal applied to the interconnect is set to F (GHz), a length of the diffusion region on the short side in a direction parallel or perpendicular to an extending direction of the interconnect is equal to or less than 25/F (μm) and
a length of the non-diffusion region on the short side in the direction parallel or perpendicular to the extending direction of the interconnect is equal to or less than 25/F (μm).

4. The semiconductor device according to claim 1, wherein the diffusion region and the non-diffusion region include long sides in the direction parallel to the extending direction of the interconnect.

5. The semiconductor device according to claim 1, wherein either the diffusion region or the non-diffusion region is disposed in an island shape in a region where the interconnect is bent.

6. The semiconductor device according to claim 1, wherein the diffusion region includes:
a plurality of island portions which are disposed separately from each other; and
connection portions which have a smaller width than that of the island portion when seen in a plan view, and are connected to the island portions, and
the non-diffusion region is separated by the diffusion region.

7. The semiconductor device according to claim 1, wherein an areal average value of a areal density of the acceptors obtained by combining the diffusion region with the non-diffusion region is equal to or more than 1×10¹⁰ cm⁻² and equal to or less than 1×10¹² cm⁻².

8. The semiconductor device according to claim 1, wherein a hulk resistivity of the silicon substrate is equal to or more than 300Ωcm.

9. The semiconductor device according to claim 1, wherein the frequency of the high frequency signal applied to the interconnect is equal to or more than 0.1 GHz.

10. The semiconductor device according to claim 9, further comprising:
a bias generation circuit that generates a power supply voltage: and
a control circuit that controls the high frequency signal,
wherein the bias circuit or the control circuit is connected to the interconnect.

11. A method of manufacturing a semiconductor device, comprising:
a first process of forming a first insulating layer over a silicon substrate, and forming a diffusion region into which acceptors are introduced and a non-diffusion region which is disposed alternately with the diffusion region and into which the acceptors are not introduced, on the silicon substrate; and
forming an interconnect over the first insulating layer.

12. The method of manufacturing a semiconductor device according to claim 11, wherein the first process further comprises forming a silicon layer so as to contact with the top of the first insulating layer,
further comprises:
forming an element isolation region in the silicon layer;
forming a semiconductor element in the silicon layer;
forming an insulating interlayer over the silicon layer, the element isolation region, and the semiconductor element;
forming a via in the insulating interlayer;
forming the interconnect over the insulating interlayer so as to be connected to the semiconductor element through the via.

13. The method of manufacturing a semiconductor device according to claim 11, wherein in the first process, the diffusion region is formed by introducing the acceptors into the silicon substrate, and then the first insulating layer is formed over the silicon substrate.

14. The method of manufacturing a semiconductor device according to claim 11, wherein in the first process, the first insulating layer is formed, and then the diffusion region is formed by introducing the acceptors into the silicon substrate through the first insulating layer.

15. The method of manufacturing a semiconductor device according to claim 12, wherein in the first process, the silicon layer is formed, and then the diffusion region is formed by introducing the acceptors into the silicon substrate through the silicon layer and the first insulating layer.

16. An SOI substrate comprising:
a diffusion region which is provided in a silicon substrate, and into which acceptors are introduced;
a non-diffusion region which is disposed in the silicon substrate alternately with the diffusion region, and into which the acceptors are not introduced;
a first insulating layer which is provided so as to contact with the top of the silicon substrate; and
a silicon layer which is provided so as to contact with the top of the first insulating layer.
